(19) United States
(12) Patent Application Publication
(10) Pub. No.: US 2025/0223220 A1
(43) Pub. Date: Jul. 10, 2025

(54) COLOR GLASS PANEL WITH REDUCED SPODUMENE CRYSTALS AND METHOD OF FORMING SAME

(71) Applicant: CORNING INCORPORATED, CORNING, NY (US)

(72) Inventors: Benjamin Dillinger, Big Flats, NY (US); Jill Marie Hall, Elmira, NY (US); Yuhui Jin, Painted Post, NY (US); Liming Li, Corning, NY (US); Meng Shang, Painted Post, NY (US); Ljerka Ukrainczyk, Ithaca, NY (US); Hao Zhou, Painted Post, NY (US)

(21) Appl. No.: 18/978,915

(22) Filed: Dec. 12, 2024

Related U.S. Application Data
(60) Provisional application No. 63/617,971, filed on Jan. 5, 2024.

(51) Int. Cl. C03C 4/02; B24B 7/24; C03B 32/02; C03C 10/00; C03C 15/00; H05K 5/03

(52) U.S. Cl. CPC C03C 4/02; B24B 7/241; C03B 32/02; C03C 10/0027; C03C 15/00; H05K 5/03; C03C 2204/00

(57) ABSTRACT

Disclosed herein are embodiments of a color glass panel. The color glass panel includes a glass body having a first major surface and a second major surface opposite the first major surface. The glass body is made from an alkali aluminosilicate glass composition containing Li₂O. At least one of the first major surface or the second major surface has a length and a width, and the length and width define an area. A ratio of a spodumene crystal area of spodumene crystals to the area is 2% or less. Further, a transmittance through the glass panel from the first major surface to the second major surface is less than about 92% for at least one wavelength in a range from about 380 nm to about 750 nm.

### CROSS REFERENCE TO RELATED APPLICATION

This application claims the benefit of priority under 35 U.S.C. § 119 of U.S. Provisional Application Ser. No. 63/617,971 filed on Jan. 5, 2024, the content of which is relied upon and incorporated herein by reference in its entirety.

### BACKGROUND

The disclosure relates to glass panels and, in particular, to glass panels configured to exhibit coloration after heat treatment.

Glass is incorporated into a variety of consumer electronic devices, especially those including displays. Such glass is designed, in part, to protect the displays, and ion exchangeable glasses, such as alkali aluminosilicate glasses, are often used because of the resistance to drops and impacts. Additionally, glass is also desirable aesthetically from a visual and tactile perspective. For this reason, glass is also being incorporated into non-display portions of consumer electronic devices, and for these applications, coloration of the glass is desirable.

### SUMMARY

According to a first aspect, embodiments of the present disclosure relate to a color glass panel. The color glass panel includes a glass body comprising a first major surface and a second major surface opposite the first major surface. The glass body comprises an alkali aluminosilicate glass composition containing Li₂O. At least one of the first major surface or the second major surface comprises a spodumene crystal ratio equal to or less than about 5%, for example equal to or less than about 4%, equal to or less than about 3%, or equal to or less than about 2%. Further, a transmittance through the glass panel from the first major surface to the second major surface may be less than about 92% for at least one wavelength in a range from about 380 nm to about 750 nm.

According to a second aspect, embodiments of the present disclosure relate to an electronic device comprising a housing. The housing comprises a color glass panel according to the first aspect.

According to a third aspect, embodiments of the present disclosure relate to a method of preparing a color glass panel. In the method, a glass panel is pre-treated. The glass panel comprises a first major surface, a second major surface opposite the first major surface, and a glass body disposed between the first major surface and the second major surface. The glass panel comprises an alkali aluminosilicate glass composition containing Li₂O. The pre-treating may remove or alter at least one of the first major surface or the second major surface up to a depth of 50 μm in the glass body. Further, in the method, the glass panel may be heat treated, after the pre-treating, at a temperature in a range from 500° C. to 700° C. for 1 hour to 20 hours. The heat treating causes a transmittance through the glass panel from the first major surface to the second major surface to change from at least about 92% across wavelengths in a range from about 380 nm to about 750 nm to less than about 92% for at least one wavelength in the range from about 380 nm to about 750 nm.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary and are intended to provide an overview or framework to understanding the nature and character of the claims.

### BRIEF DESCRIPTION OF THE DRAWINGS

The accompanying drawings are included to provide a further understanding and are incorporated in and constitute a part of this specification. The drawings illustrate one or more embodiment(s), and together with the description serve to explain principles and operation of the various embodiments. In the drawings:

FIG. 1 depicts a color glass panel, according to one or more exemplary embodiments;

FIG. 2 is flow diagram of a method for preparing a color glass panel, according to one or more exemplary embodiments;

FIG. 3 is a glass article, in particular a consumer electronic device, incorporating a color glass panel, according to one or more exemplary embodiments;

FIG. 4 is a table providing pictures of glass coupons subjected to heat treatment including a control and three coupons pre-treated according to one or more exemplary embodiments;

FIG. 5 is a graph of the number of spodumene crystals counted per sample area for the coupons shown in FIG. 4;

FIG. 6 is a graph of the size of spodumene crystals for the coupons shown in FIG. 4;

FIG. 7 is a table providing pictures of glass coupons subjected to heat treatment including a control and six coupons pre-treated according to one or more exemplary embodiments;

FIG. 8 is a graph of the number of spodumene crystals counted per area for the coupons shown in FIG. 7; and

FIG. 9 is a graph of the size of spodumene crystals for the coupons shown in FIG. 7.

### DETAILED DESCRIPTION

Reference will now be made in detail to various embodiments of color glass panels having reduced spodumene crystal growth and methods of forming such color glass panels, examples of which are illustrated in the accompanying drawings. The glass panels disclosed herein are comprised of an alkali aluminosilicate glass composition, and through heat treatment, coloration is induced in the glass panels. The color glass panels can then be incorporated into various consumer electronic devices, architectural structures, or automotive applications as decorative elements. However, in certain circumstances, such heat treatment can lead to the formation of spodumene crystals on the surface of the glass panel, especially at the temperatures and times necessary to provide consistent coloration of the glass panel, which may render them unusable as decorative elements.

According to the present disclosure, the glass panels are pre-treated before heat treatment by removing the surface of the glass panel or altering the glass panel in the vicinity of the surface. Such removal or alteration of the glass surface can be accomplished through etching, leaching, or polishing. In particular, etching and polishing of the glass panel can decrease the surface roughness, removing sharp peaks and/or surface contamination that may serve as nucleation sites for spodumene crystals, and leaching can remove lithium oxide (Li₂O) from the surface region of the glass panel and inhibit formation of spodumene crystals at the surface thereof. In this way, the pre-treatment can substantially diminishe the number and size of spodumene crystals that may be produced by subsequent heat-treatment, allowing the glass panels to be heat treated at temperatures and for times desired to produce consistent coloration. These and other aspects and advantages of the disclosed color glass panels and methods of forming same will be described more fully below. Embodiments discussed herein are presented by way of illustration and not limitation.

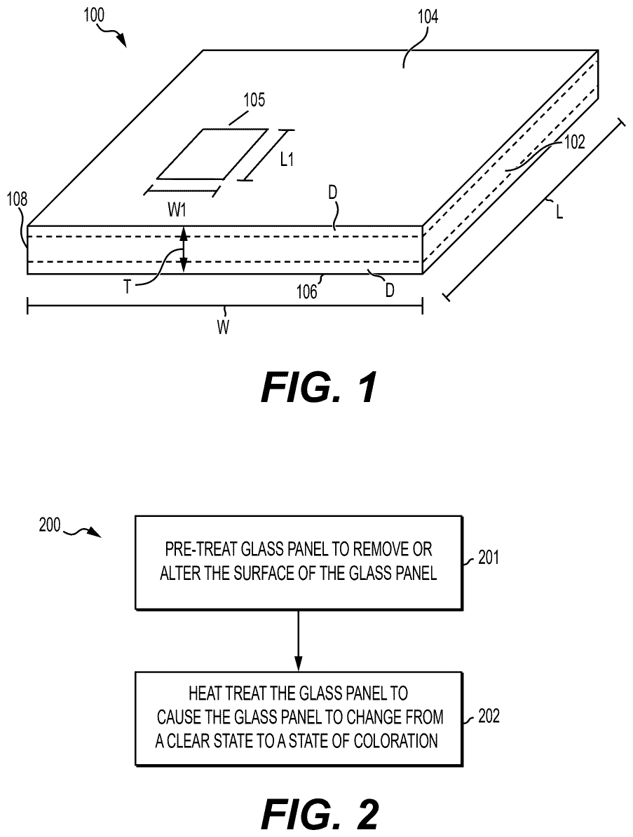

FIG. 1 depicts an embodiment of a glass panel 100 according to the present disclosure. The glass panel 100 includes a glass body 102 having a first major surface 104 and a second major surface 106 opposite the first major surface 104. As shown in FIG. 1, the first major surface 104 and the second major surface 106 may be substantially flat. However, in one or more other embodiments, either or both of the first major surface 104 and the second major surface 106 may include a curvature. A minor surface 108 extends around a periphery of the glass panel 100 and connects the first major surface 104 to the second major surface 106. The first major surface 104 and the second major surface 106 define a thickness T of the glass panel 100 therebetween. In one or more embodiments, the thickness T may be in a range from about 2 mm to about 3 mm, for example in a range from about 2.2 mm to about 3 mm, in a range from about 2.4 mm to about 3 mm, in a range from about 2.6 mm to about 3 mm, in a range from about 2.8 mm to about 3 mm, in a range from about 2 mm to about 2.8 mm, in a range from about 2 mm to about 2.6 mm, in a range from about 2 mm to about 2.4 mm, in a range from about 2 mm to about 2.2 mm, including all ranges and subranges therebetween. In some embodiments, the thickness T may be in a range from about 2.65 mm to about 2.85 mm.

The glass body 102 comprises an alkali aluminosilicate glass composition that contains lithium oxide (Li₂O), which renders glass panel 100 susceptible to formation of spodumene crystals (crystals of LiAl(SiO₃)₂). An example of such an alkali aluminosilicate glass composition comprises SiO₂ in an amount in a range from about 40 mol % to about 80 mol %, for example in a range from about 50 mol % to about 80 mol %, in a range from about 60 mol % to about 80 mol %, in a range from about 70 mol % to about 80 mol %, in a range from about 50 mol % to about 70 mol %, or in a range from about 50 mol % to about 60 mol %, including all ranges and subranges therebetween.

The glass body may further comprise Al₂O₃ in an amount in a range from 0 mol % to about 25 mol %, for example in a range from about 5 mol % to about 25 mol %, in a range from about 10 mol % to about 25 mol %, in a range from about 15 mol % to about 25 mol %, in a range from about 20 mol % to about 25 mol %, in a range from about 0 mol % to about 20 mol %, in a range from about 0 mol % to about 15 mol %, in a range from about 0 mol % to about 10 mol %, or in a range from about 0 mol % to about 5 mol %, including all ranges and subranges therebetween.

The glass body may further comprise R₂O in an amount in a range from about 1 mol % to about 35 mol %, wherein R₂O comprises Li₂O and at least one of Na₂O or K₂O. For example, the glass body may comprise R₂O in an amount in a range from about 1 mol % to about 30 mol %, in a range from about 1 mol % to about 25 mol %, in a range from about 1 mol % to about 20 mol %, in a range from about 1 mol % to about 15 mol %, in a range from about 1 mol % to about 10 mol %, in a range from about 1 mol % to about 5 mol %, in a range from about 5 mol % to about 35 mol %, in a range from about 10 mol % to about 35 mol %, in a range from about 15 mol % to about 35 mol %, in a range from about 20 mol % to about 35 mol %, in a range from about 25 mol % to about 35 mol %, or in a range from about 30 mol % to about 35 mol %, including all ranges and subranges therebetween.

In one or more embodiments, the glass composition may comprise Al₂O₃ in an amount in a range from about 7 mol % to about 20 mol %, Li₂O in an amount in a range from about 1 mol % to about 20 mol %, and Na₂O in an amount in a range from about 5 mol % to about 34 mol %. In one or more embodiments, the glass composition may also comprise B₂O₃ in an amount in a range from 0 mol % to about 10 mol %, K₂O in an amount in a range from 0 mol % to about 3 mol %, MgO in an amount in a range from 0 mol % to about 8.5 mol %, ZnO in an amount in a range from 0 mol % to about 2 mol %, P₂O₅ in an amount in a range from 0 mol % to about 10 mol %, CaO in an amount in a range from 0 mol % to about 1.5 mol %, Rb₂O in an amount in a range from 0 mol % to about 20 mol %, and Cs₂O in an amount in a range from 0 mol % to about 20 mol %. Other oxides may also be present such SrO, BaO, and ZrO₂, amongst others.

In one or more embodiments, the alkali aluminosilicate glass composition may be doped with at least one of Au, Ag, Cu, Ni, Co, Fe, Mn, Cr, V, Ti, La, Ce, Pr, Nd, Sm, Eu, Gd, Tb, Dy, Ho, Er, Tm, Yb, or Lu, which may be added to produce a desired coloration of the glass panel 100 upon heat treatment. In one or more embodiments, the dopants may be provided in an amount in a range from about 106 mol % to about 10 mol %. Such coloration may be any of a variety of hues of red, orange, yellow, green, blue, or violet. Examples of alkali aluminosilicate glass compositions, including dopants, and heat treatments to produce a desired color can be found in International Publication No. WO2022266405A1 (“Colored glass articles having improved mechanical durability,” filed on Jun. 17, 2022, published on Dec. 22, 2022).

In one or more embodiments, heat treatment of the glass panel 100 causes the glass panel to transition from a clear state to a state of coloration. In one or more embodiments, the coloration can be described by the transmittance of visible light through the glass panel 100 from the first major surface 104 to the second major surface 106. In one or more embodiments, the transmittance of visible light when in the clear state may be at least 92% across all wavelengths in a range from about 380 nanometers (nm) to about 750 nm when measured with a Konica Minolta CM 3700 spectrophotometer. In one or more embodiments, the transmittance in the state of coloration may be less than 92%, in particular in a range from about 10% to about 92% for at least one wavelength in the range from about 380 nm to about 750 nm when measured with a Konica Minolta CM 3700 spectrophotometer.

In one or more embodiments, coloration can be described in terms of CIE L*a*b* color space. In such embodiments, the glass panel 100 may have an L* parameter in a range from about 55 to about 96.5. Further, in one or more embodiments, the glass panel 100 may have an a* parameter with an absolute value of at least about 0.3 (e.g., |a*|≥0.3), and in one or more embodiments, the glass panel 100 may have an a* parameter with an absolute value of up to about 60 (e.g., |a*|≤60). In one or more embodiments, the glass panel 100 may have a b* parameter with an absolute value of at least about 0.5 (e.g., |b*|≥0.5), and in one or more embodiments, the glass panel 100 may have a b* parameter with an absolute value of up to about 90 (e.g., |b*|≤90). Further, at least one of a* or b* may be nonzero. In one or more of the foregoing embodiments, the L*, a*, and b* parameters may be measured under F2 illumination and a 10° standard observer angle. Color measurements are made with a Konica Minolta CM 3700 spectrophotometer.

As mentioned above, heat treatment of the glass panel 100 to induce coloration may cause formation of spodumene crystals on or in the vicinity of the first major surface 104 and/or the second major surface 106. If the number of spodumene crystals is too great or the size of the spodumene crystals is too large, the glass panel 100 may become unusable for decorative purposes because the spodumene crystals may be visible to the naked eye. According to the present disclosure, the glass panel 100 may be pre-treated before heat treatment to reduce the number and size of spodumene crystals by removing nucleation sites for spodumene crystal formation or reducing the amount of lithium oxide available to form spodumene crystals.

As shown in FIG. 1, the glass panel 100 may be rectangular, comprising a length L and a width W. Thus, the area of the glass panel is the product of the length L and width W. However, in other embodiments, the glass panel 100 may be a different shape, such as any of a variety of curved or polygonal shapes, or shapes including both curved and straight edges. The first major surface 104 and/or the second major surface 106 further includes a sample area 105 comprising a length L1 and a width W1. The sample area in FIG. 1 is shown as rectangular having an area defined by the product of length L1 and width W1. However, like glass panel 100, sample area 105 may have other shapes, and the area thereof may be determined by appropriate geometric formula. Sample area 105 may have an area (for example, L1×W1) equal to or less than the total area of the first major surface 104 or the second major surface 106 (e.g., L×W). In embodiments, the sample area may have an area equal to or greater than 2500 mm². A ratio of an area of spodumene crystals within sample area 105 to the total area of the sample area may be equal to or less than about 0.05, for example equal to or less than about 0.04, equal to or less than about 0.03, or equal to or less than about 0.02. That is, for example, the total area of spodumene crystals may be equal to or less than about 5% of the total area of the sample area. In one or more embodiments, the ratio of the area of the spodumene crystals within sample area 105 to the total area of sample area 105 may be equal to or less than about 0.01. Further, in one or more embodiments, the spodumene crystals may comprise an average size of 20 μm or less, wherein size refers to the largest dimension of a spodumene crystal. In one or more embodiments, the spodumene crystals may comprise a number density of 110 spodumene crystals per mm² of surface area of the first and/or second major surface, or less than 110 spodumene crystals per mm². In one or more embodiments, elimination of all spodumene crystals may not be possible, and thus, there may be at least 1 spodumene crystal per mm² present in the glass panel 100. By comparison, a glass panel prepared without pre-treatment may comprise as many as 600 spodumene crystals per mm², or more and/or include spodumene crystals covering more than 5% of the area of the first major surface and/or second major surface.

Having described the glass panel 100 after heat treatment, a method of preparing the glass panel 100 involving pre-treating the glass panel 100 before heat treatment will now be discussed. FIG. 2 provides a flow diagram of a method 200 for preparing the glass panel 100, and FIG. 2 will be discussed in relation to the glass panel 100 of FIG. 1 for reference. In a first step 201 of the method 200, a glass panel 100 is pre-treated to remove or alter at least one of the first major surface 104 or the second major surface 106 up to a depth D of 50 μm in the glass body 102. As mentioned above, pre-treating the glass panel 100 can remove nucleation sites for the formation of spodumene crystals from the first major surface 104 and/or second major surface 106 of the glass panel 100 and/or depletes lithium oxide (Li₂O) from a surface region to limit the formation of spodumene crystals. In a second step 202 of the method 200, the glass panel 100 is then heat treated at a temperature in a range from 500° C. to 700° C. for 1 hour to 20 hours to cause the glass panel 100 to change from a state of being substantially transparent or clear to a state in which the glass panel 100 exhibits coloration.

The pre-treating of the first step 201 can be performed in a variety of suitable ways. In one or more embodiments, the first step 201 of pre-treating involves etching the glass panel 100 to remove surface defects and decrease surface roughness. In one or more such embodiments, the etching involves exposing at least one of the first major surface 104 or the second major surface 106 to an etchant. In such embodiments, the etchant may be acidic or basic.

In one or more embodiments involving an acid etchant, the etchant may comprise about 1 weight percent (wt %) to about 20 wt % of hydrofluoric acid. Further, in one or more such embodiments, the acid etching is performed at room temperature or may be performed at an elevated temperature. For example, in one or more embodiments, the acid etching may be performed at a temperature in a range from about 20° C. to about 45° C.

In one or more embodiments involving a basic etchant, the basic etchant may comprise about 10 wt % to about 70 wt % of at least one of NaOH or KOH. In one or more such embodiments, the basic etching may be performed at an elevated temperature, such as a temperature in a range from about 90° C. to about 165° C.

In one or more embodiments, the etching, whether acidic or basic, may be performed for a time sufficient to remove from about 1 micrometer (μm) to about 50 μm from at least one of the first major surface 104 or the second major surface 106. In one or more embodiments, acid etching may be performed for at least about 5 minutes. In one or more embodiments, acid etching may be performed for up to about 180 minutes. In one or more embodiments, the basic etching may be performed for at least about 10 minutes. In one or more embodiments, the basic etching may be performed for up to about 180 minutes.

After etching, in one or more embodiments, the etched first major surface and/or second major surface may exhibit a surface roughness Sa of about 80 nm or less as measured according to ISO 25178, where the parameter Sa refers to the arithmetical mean height of a scale limited surface area.

By pre-treating using etching, surface contamination is removed, and the surface is substantially free from sharp defects and flaws that may provide nucleation sites for spodumene crystal formation.

In one or more embodiments, the first step 201 of pre-treating involves polishing at least one of the first major surface 104 or the second major surface 106. In one or more such embodiments, the polishing removes from about 5 μm to about 40 μm from the at least one of the first major surface 104 or the second major surface 106.

In one or more embodiments, the polishing may be performed by abrading the at least one of the first major surface 104 or the second major surface 106 with a slurry, for example an aqueous slurry, comprising polishing particles, such as particles of rare earth oxides. The polishing may be performed through chemical mechanical polishing and associated equipment. In one or more embodiments, the polishing particles may comprise a median particle size (D50) in a range from about 2.3 μm to about 3.6 μm. In one or more embodiments, the polishing particles may comprise ceria as a primary component. Such rare earth oxide polishing particles, in particular particles high in ceria content, are known to provide a good finish, allow for fast polishing speed, and have a long service life. However, in one or more other embodiments, other abrasive particles can be used instead of or in conjunction with rare earth oxide polishing particles.

In one or more embodiments, after polishing, the polished first major surface 104 or second major surface 106 may comprise a surface roughness Sa of about 10 nm or less when measured according to ISO 25178. As with etching, pre-treating by polishing may remove surface contamination and produce a surface substantially free from sharp defects and flaws that may provide nucleation points for spodumene crystal formation.

In one or more embodiments, the first step 201 of pre-treating involves exposing the glass panel 100 to an acid leachant. In one or more such embodiments, the acid leachant may comprise from about 1 wt % to about 20 wt % of at least one of HCl, H₂SO₄, or HNO₃, for example from about 2 wt % to about 20 wt %, from about 5 wt % to about 20 wt %, from about 10 wt % to about 20 wt %, or from about 15 wt % to about 20 wt % of at least one of HCl, H₂SO₄, or HNO₃. In one or more embodiments, the glass panel 100 may be exposed to the acid leachant at an elevated temperature, such as a temperature in a range from about 40° C. to about 95° C., for example in a range from about 50° C. to about 95° C., from about 60° C. to about 95° C., from about 70° C. to about 95° C., or from about 80 to about 95, including all ranges and subranges therebetween. In one or more embodiments, the glass panel 100 may be exposed to the acid leachant for a time in a range from about 30 minutes to about 180 minutes, for example from about 40 minutes to about 180 minutes, from about 60 minutes to about 180 minutes, from about 80 minutes to about 180 minutes, from about 100 minutes to about 180 minutes, from about 120 minutes to about 180 minutes, from about 140 minutes to about 180 minutes, or from about 169 minutes to about 180 minutes, including all ranges and subranges therebetween.

In one or more embodiments, after exposing the glass panel 100 to the acid leachant, a first concentration of Li₂O in a region from the first major surface 104 and/or the second major surface 106 to a depth D of about 100 nm may be less than a second concentration of Li₂O at a midpoint of the thickness T of the glass body 102 between the first major surface 104 and the second major surface 106.

As mentioned above, spodumene crystals are comprised of lithium (LiAl(SiO₃)₂), and therefore, by leaching lithium from the surface region of the glass panel 100 less lithium is available to form spodumene crystals.

The color glass panels 100 described herein may be used for a variety of applications including, for example, for housings for consumer electronic devices; for architectural glass applications; for automotive or vehicular glass applications; or for commercial or household appliance applications. In one or more embodiments, a consumer electronic device (e.g., smartphones, tablet computers, watches, personal computers, ultrabooks, televisions, and cameras), an architectural glass, and/or an automotive glass may comprise a color glass panel 100 as described herein.

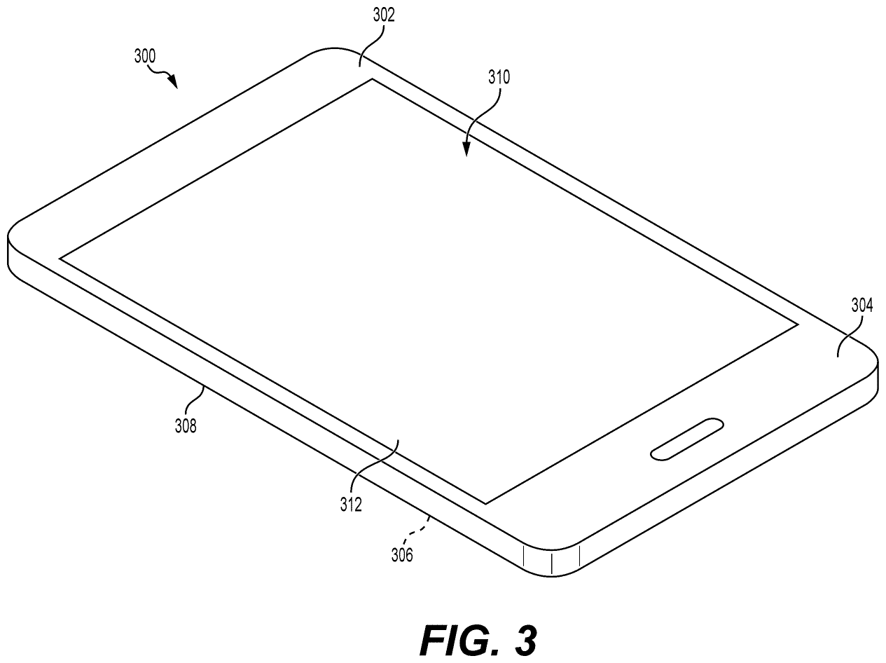

An example article incorporating any of the color glass panels 100 disclosed herein is shown in FIG. 3. Specifically, FIG. 3 shows a consumer electronic device 300 including a housing 302 having front 304, back 306, and side surfaces 308; electrical components (not shown) that are at least partially inside or entirely within the housing 302 and including for example a controller, a memory, and a display 310 at or adjacent to the front surface of the housing 302; and a cover substrate 312 at or over the front surface of the housing 302 such that it is over the display. In one or more embodiments, at least a portion of housing 302, such as the back 306, may include any of the color glass panels 100 disclosed herein.

### EXPERIMENTAL EXAMPLES

### Example 1

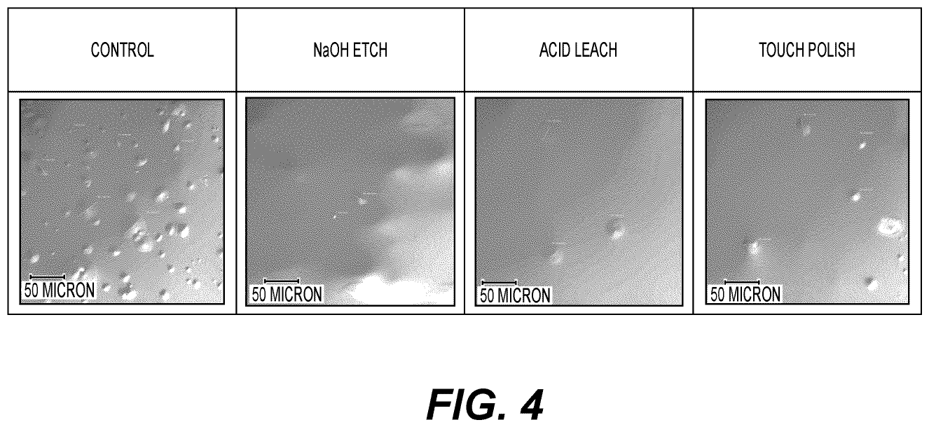

Several glass coupons (50 mm×50 mm) having a composition of alkali aluminosilicate glass were prepared. The glass coupons' lateral dimensions were 50 mm×50 mm. All of the glass coupons were subjected to heat treatment at 600° C. for 6 hours. According to existing practice, glass coupons of a first type were not pre-treated and acted as a control to provide a comparison for the amount of spodumene crystals caused by heat treating. The remaining glass coupons were pre-treated according to three pre-treatments described in the present disclosure. In particular, glass coupons of a second type were subjected to a basic etching using 50% NaOH at 120° C. for 40 minutes to remove about 10 μm from each opposing major surface of the coupon. Glass coupons of the third type were subjected to acid leaching on each major surface of the coupons using HNO₃ (1 mol/L) at 40° C. for 60 minutes, and glass coupons of a fourth type were subjected to polishing on each major surface to remove about 2 μm from the opposing major surfaces. Examples of the glass coupons of each type after heat treatment and under 50× magnification with optical microscopy are depicted in FIG. 4. As can be seen, the glass coupons of the first type (control) exhibited significantly more spodumene crystals than the coupons that were pretreated.

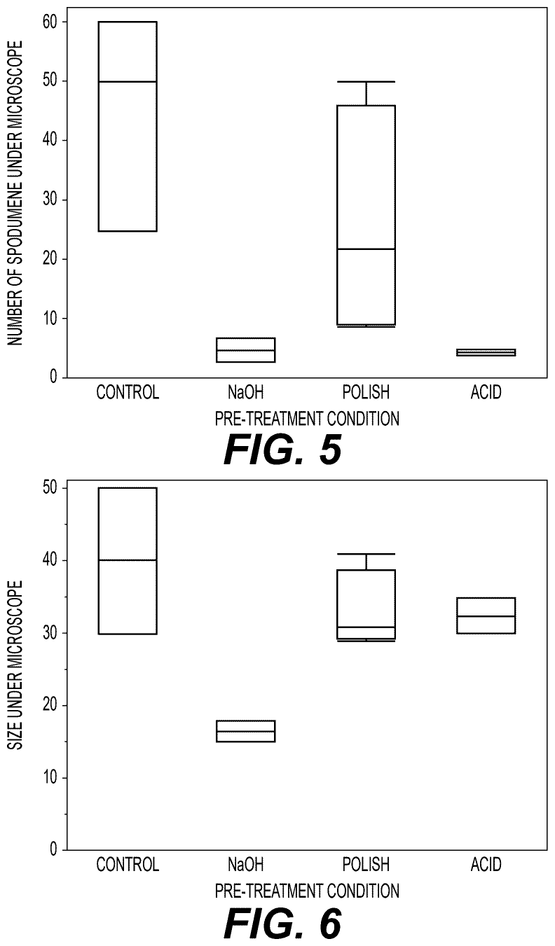

FIG. 5 provides a graph of the number of spodumene crystals after heat treatment. The spodumene crystals were counted under magnification. The spodumene crystals were counted in 2 to 5 areas (each area was approximately 300 μm×300 μm) on each of the sample coupons (1 to 5 coupons per type). FIG. 5 provides the box plot of the number of spodumene crystals counted in each of the areas of the heat treated glass coupons. As can be seen, the average number of spodumene crystals counted per area is significantly higher for the glass coupons of the first type that were not pre-treated than for any of the coupons according to any of the three pre-treatment types. In particular, the glass coupons of the first type (control) exhibited about 50 spodumene crystals on average per area, whereas the glass coupons of the second, third, and fourth types exhibited less than about 25 spodumene crystals on average per area. Thus, all three methods of pre-treatment were effective at reducing the number of spodumene crystals.

FIG. 6 provides a graph summarizing the size of the spodumene crystals detected under magnification of the glass coupons of the four types. In particular, FIG. 6 provides the box plot of the size of the spodumene crystals. As can be seen, the average size of the crystals is reduced for the glass coupons of the second, third, and fourth types that were pre-treated. In particular, the glass coupons of the first type (control) exhibited spodumene crystals having an average size of about 40 μm. The glass coupons of the second, third, and fourth types all exhibited spodumene crystals having an average size of less than 35 μm.

From FIGS. 5 and 6, it can be seen that, in this set of experiments, the basic etch produced the best overall results in terms of reducing the average number of spodumene crystals (about 5 on average per area) and the average size of spodumene crystals (less than 20 μm on average). However, it can also be seen that acid leaching also reduced the average number of spodumene crystals to about the same level as basic etching.

### Example 2

Several additional glass coupons of alkali aluminosilicate glass were prepared. All of the glass coupons were heat treated at 600° C. for 6 hours. According to existing practice, glass coupons of a first type were not pre-treated and acted as a control for comparison with respect to pre-treated glass coupons. Glass coupons of second, third, fourth, and fifth types were subjected to basic etching using an aqueous solution of 50% NaOH at 120° C. The glass coupons of the second type were etched to remove about 1 μm from the major surface, and glass coupons of the third type were etched to remove about 5 μm from the major surface. Glass coupons of the fourth type were etched to remove about 10 μm, and glass coupons of the fifth type were etched to remove about 20 μm. Glass coupons of sixth and seventh types were polished to remove about 10 μm and about 20 μm from the major surface, respectively.

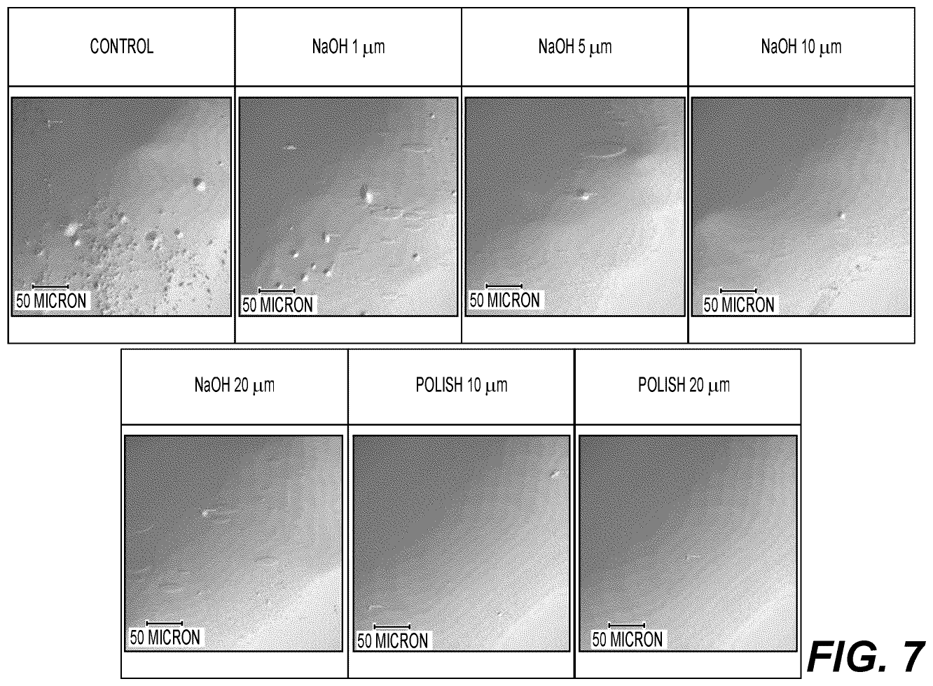

FIG. 7 depicts examples of glass coupons of each type after heat treatment and under 50× magnification using optical microscopy. As can be seen, the glass coupons of the first type (control) included several visible spodumene crystals. Glass coupons of the second through seventh types all exhibited far fewer visible spodumene crystals. Further, with respect to the glass coupons treated with basic etching, the number of visible spodumene crystals also decreased with increased etching depth. Similarly, the number of visible spodumene crystals decreased with increased polishing depth.

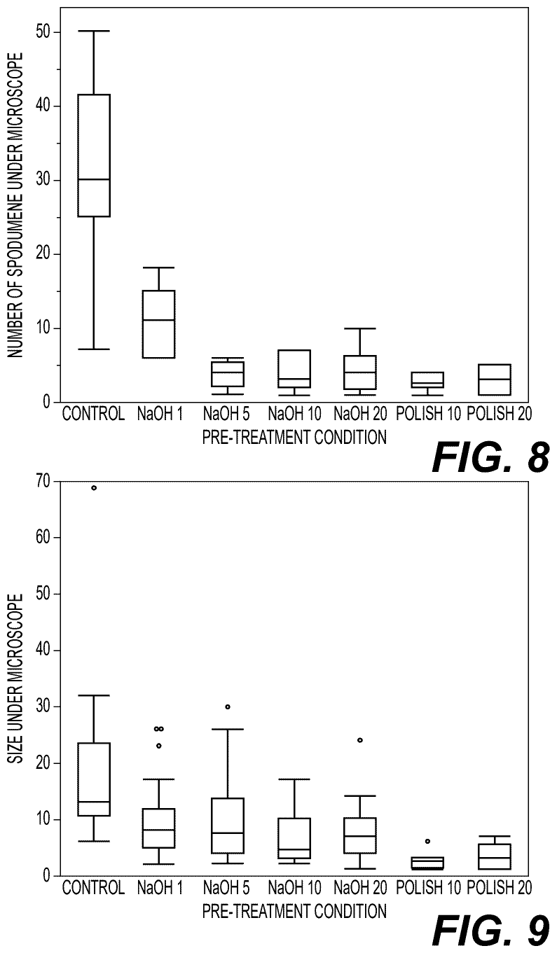

FIG. 8 provides a graph of the number of spodumene crystals after heat treatment. Like Example 1, the spodumene crystals were counted under magnification, and the spodumene crystals were counted in 2 to 5 areas (each area was approximately 300 μm×300 μm) on 2 to 5 coupons of each type. FIG. 8 provides the box plot of the number of spodumene crystals for glass coupons of each type. As can be seen in FIG. 8, the number of spodumene crystals on average per area is 30 for glass coupons of the first type (control), and for glass coupons of the second through the seventh types, the number of spodumene crystals on average per area is less than 15. For glass coupons of the third through seventh types, the number of spodumene crystals on average per area is less than 5. Thus, number of spodumene crystals can be reduced by removing just 1 μm from the surface of the glass.

FIG. 9 provides a graph summarizing the size of the spodumene crystals detected under magnification of the glass coupons of the seven types. In particular, FIG. 9 provides a box plot of the size of the spodumene crystals. As can be seen, the average size of the spodumene crystals is reduced for the pre-treated glass coupons. In particular, the glass coupons of the first type (control) exhibited spodumene crystals having an average size (average of the largest dimension) of about 13 μm. The glass coupons of the second through seventh types all exhibited spodumene crystals having an average size of less than about 10 μm.

From FIGS. 8 and 9, it can be seen that, in this set of experiments, both the basic etch and polishing were effective in reducing the average number of spodumene crystals (15 on average per area or less) and the average size of spodumene crystals (less than about 10 μm on average), especially when spodumene crystals having a size greater than about 5 μm were removed from the surface (5 or less spodumene crystals per area on average and spodumene crystals having a size less than about 10 μm on average).

### Example 3

Seven example glass coupons 50 mm×50 mm were prepared according to Example 2 and an example acid leaching coupon according to Example 1 were subjected to image analysis to determine the total area of spodumene crystals on a pre-treated glass surface. An image defining a sample area 105 was obtained from the glass coupon using a polarized light polariscope and camera. The sample area image was first transformed to gray scale, each pixel of the gray scale image having a value on a scale from 0 to 255, wherein 0 represents black and 255 represents white. The image was then transformed into a black and white image wherein pixels having a value equal to or less than 200 were rendered as black pixels and pixels having a value greater than 200 were rendered as white pixels. Using image analysis software, the total number of pixels in the image (white pixels plus black pixels) were counted as well as the total number of white pixels. Knowing the size (area) of each pixel from the imaging apparatus (e.g., camera) sensor characteristics, a “spodumene crystal area” (SCR) was calculated as the total area of all the white pixels in the sample area divided by the total area of the sample area and expressed as a percent. The SCR for the sample area may be used to represent the SCR for a surface of the glass coupon. Table 1 provides a summary of the image analysis.

TABLE 1
Spodumene Crystal Ratio of Coupons with Various
Pre-Treaments and without Pre-Treatment

| Sample | SCR (%) |
|---|---|
| Control | 6.02 |
| Acid leaching | 4.11 |
| NaOH etch (1 μm) | 0.59 |
| NaOH etch (5 μm) | 0.42 |
| NaOH etch (10 μm) | 1.05 |
| NaOH (20 μm) | 0.48 |
| Polish (10 μm) | 0.32 |
| Polish (20 μm) | 0.38 |

Thus, from Table 1, it can be seen that pre-treating reduces the spodumene crystal ratio from 6.02% to below 5%. In particular, for the etching and polishing pre-treatments, the spodumene crystal ratio SCR was reduced to below 2%, in particular about 1% or less.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred. In addition, as used herein, the article “a” is intended to include one or more than one component or element and is not intended to be construed as meaning only one.

It will be apparent to those skilled in the art that various modifications and variations can be made without departing from the spirit or scope of the disclosed embodiments. Since modifications, combinations, sub-combinations and variations of the disclosed embodiments incorporating the spirit and substance of the embodiments may occur to persons skilled in the art. the disclosed embodiments should be construed to include everything within the scope of the appended claims and their equivalents.

What is claimed is:

1. A color glass panel, comprising:
a glass body comprising a first major surface and a second major surface opposite the first major surface, the glass body comprising an alkali aluminosilicate glass composition containing Li₂O; and
wherein at least one of the first major surface or the second major surface comprises a spodumene crystal ratio equal to or less than about 0.02; and
wherein a transmittance through the glass panel from the first major surface to the second major surface is less than 92% for at least one wavelength in a range from 380 nm to 750 nm.

2. The color glass panel of claim 1, wherein the spodumene crystals comprise an average size of 20 μm or less.

3. The color glass panel of claim 1, wherein the spodumene crystals comprise a number density of 110 spodumene crystals per mm² or less.

4. The color glass panel of claim 1, wherein, according to CIE L*a*b* color space, the glass panel comprises an L* parameter in a range from 55 to 96.5 and at least one of an a* parameter having an absolute value of at least 0.3 or a b* parameter having an absolute value of at least 0.5 as measured under F2 illumination and a 10° standard observer angle.

5. The color glass panel of claim 1, wherein the at least one of the first major surface or the second major surface comprises a polished surface with an average surface roughness Sa of 10 nm or less.

6. The color glass panel of claim 1, wherein a first concentration of Li₂O in a region from the at least one of the first major surface or the second major surface to a depth of about 100 nm is less than a second concentration of Li₂O at a midpoint of a thickness of the glass body between the first major surface and the second major surface.

7. The color glass panel of claim 1, wherein the at least one of the first major surface or the second major surface comprises an etched surface with an average surface roughness Sa of 80 nm or less.

8. The color glass panel of claim 1, wherein the spodumene crystal ratio is equal to or less than about 2%.

9. The color glass panel of claim 1, wherein the alkali aluminosilicate glass composition is doped with at least one of Au, Ag, Cu, Ni, Co, Fe, Mn, Cr, V, Ti, La, Ce, Pr, Nd, Sm, Eu, Gd, Tb, Dy, Ho, Er, Tm, Yb, and Lu.

10. An electronic device comprising a housing, the housing comprising a color glass panel according to claim 1.

11. A method of preparing a color glass panel, comprising:
pre-treating a glass panel comprising a first major surface, a second major surface opposite the first major surface, and a glass body disposed between the first major surface and the second major surface, the glass panel comprising an alkali aluminosilicate glass composition containing Li₂O, and wherein the pre-treating removes or alters at least one of the first major surface or the second major surface up to a depth of 50 μm in the glass body; and
heat treating the glass panel after the pre-treating at a temperature in a range from about 500° C. to about 700° C. for 1 hour to 20 hours, the heat treating causing a transmittance through the glass panel from the first major surface to the second major surface to change from at least 92% across wavelengths in a range from 380 nm to 750 nm to less than 92% for at least one wavelength in the range from 380 nm to 750 nm.

12. The method of claim 11, wherein the pre-treating comprises etching the glass panel.

13. The method of claim 12, wherein the etching further comprises exposing at least one of the first major surface or the second major surface to an etchant comprising about 1 wt % to about 20 wt % of hydrofluoric acid.

14. The method of claim 13, wherein the etching is performed at a temperature in a range from 20° C. to 45° C.

15. The method of claim 12, wherein the etching further comprises exposing at least one of the first major surface or the second major surface to an etchant comprising about 10 wt % to about 70 wt % of at least one of NaOH or KOH.

16. The method of claim 15, wherein the etching is performed at a temperature in a range from 90° C. to 165° C.

17. The method of claim 12, wherein the etching removes from about 1 μm to about 50 μm from at least one of the first major surface or the second major surface.

18. The method of claim 11, wherein the pre-treating comprises polishing at least one of the first major surface or the second major surface.

19. The method of claim 18, wherein the polishing removes from about 5 μm to about 40 μm from the at least one of the first major surface or the second major surface.

20. The method of claim 18, wherein the polishing comprises abrading the at least one of the first major surface or the second major surface with a slurry comprising polishing particles.

21. The method of claim 20, wherein the polishing particles comprise a median particle size (D50) in a range from about 2.3 μm to about 3.6 μm.

22. The method of claim 20, wherein the polishing particles comprise ceria.

23. The method of claim 11, wherein the pre-treating comprises exposing the glass panel to an acid leachant.

24. The method of claim 23, wherein the acid leachant comprises from about 1 wt % to about 20 wt % of at least one of HCl, H₂SO₄, or HNO₃.

25. The method of claim 23, wherein the exposing the glass panel to the acid leachant is performed at a temperature in a range from 40° C. to 95° C.

26. The method of claim 23, wherein the exposing the glass panel to the acid leachant is performed for a time in a range from 30 minutes to 180 minutes.
